(19) United States
(12) Patent Application Publication
(10) Pub. No.: US 2015/0224373 A1
(43) Pub. Date: Aug. 13, 2015

(54) GOLF CLUB HEAD AND MANUFACTURING METHOD THEREOF

(71) Applicant: FUSHENG PRECISION CO., LTD., Taipei (TW)

(72) Inventors: Jian-Dong FENG, Guangdong Province (CN); Tian-Wei LU, Guangdong Province (CN)

(21) Appl. No.: 14/600,002

(22) Filed: Jan. 19, 2015

(30) Foreign Application Priority Data
Feb. 10, 2014 (CN) 201410046636.X

(51) Int. Cl. A63B 53/04; C23C 14/04; C23C 14/58

(52) U.S. Cl. CPC A63B 53/04; C23C 14/5873; C23C 14/584; C23C 14/04; A63B 2053/0408

(57) ABSTRACT

A golf club head including a main body and a physical vapor deposition layer is provided. The physical vapor deposition layer is formed on a curved surface of the main body and has a laser engraved structure. The disclosure further discloses a manufacturing method of the golf club head. According to the golf club head and the manufacturing method thereof, the physical vapor deposition layer is formed on the curved surface, so the curved surface appears to have a natural metallic luster and texture. Furthermore, the laser engraved structure is formed on the physical vapor deposition layer by using the laser engraving technology, so the curved surface further appears to have a stereoscopic texture. In addition, the laser engraved structure is filled with a dye layer, so the laser engraved structure appears to have a color different from that of the physical vapor deposition layer.

### RELATED APPLICATIONS

This application claims priority to China Application Serial Number 201410046636.X, filed Feb. 10, 2014, which is herein incorporated by reference.

### BACKGROUND

1. Technical Field

The present disclosure relates to a golf club head and a manufacturing method thereof, and more particularly, to the golf club head having a curved surface with a specific radian and the manufacturing method thereof.

2. Description of Related Art

Conventional coating layers of golf club heads and a coating method thereof are about forming a coating layer on a surface of a main body of the golf club head. Each of the coating layers mainly includes a base paint, a colored paint, and a protective paint. The coating method includes: dip coating a transparent base paint on the surface of the main body of the golf club head and baking to harden; finely grinding with an abrasive belt of which the roughness is ranged from #600 to #1000, so as to slightly roughen the base paint; dip coating or spin coating a color paint on the base paint; screen-printing or hot-transfer printing a trademark or a pattern; and then dip coating a protective paint to protect the trademark or the pattern.

Although the foregoing coating method is widely used to golf club heads owing to advantages of low costs and being capable of changing designs according to requirements of products, the coating method has following disadvantages: (1) when the thickness of the coated color paint is inadequate, the colored paint cannot effectively hide the color of the surface of the main body of the golf club head; (2) when the thickness of the coated color paint is too thick, each of the coating layers flakes easily from the surface of the main body of the golf club head after prolonged use; (3) no matter whether the color paint is dip coated or spin coated, the color of the colored paint is hard to be uniform; (4) after the protective paint is worn, the colored paint is also gradually worn due to poor hardness, so as to make the surface of the main body of the golf club head loss its luster; (5) the colored paint alone can not appear with a perfect metallic luster; and (6) the conventional coating layers can not appear as stereoscopic textures. Therefore, the conventional coating layers of the golf club heads and the coating method thereof need to be further improved.

Accordingly, how to provide a golf club head to solve the aforementioned problems becomes an important issue to be solved by those in the industry.

### SUMMARY

An aspect of the disclosure is to provide a golf club head and a manufacturing method thereof, in which a physical vapor deposition layer is formed on a curved surface of a main body, so the curved surface of the main body can appear to have a natural metallic luster and texture. Furthermore, a laser engraved structure is formed on the physical vapor deposition layer by using laser engraving technology, so the curved surface of the main body can further appear as a stereoscopic texture. In addition, the laser engraved structure is filled with a dye layer, so the laser engraved structure can appear with a color different from that of the physical vapor deposition layer.

The disclosure provides a golf club head. The golf club head includes a main body and a physical vapor deposition layer. The main body has a curved surface. The physical vapor deposition layer is formed on the curved surface. The physical vapor deposition layer has a laser engraved structure.

In an embodiment of the disclosure, the laser engraved structure is a recessed structure. The golf club head further includes a dye layer, and the dye layer is filled in the laser engraved structure.

In an embodiment of the disclosure, the curved surface is a concave surface, a convex surface, or a raised and recessed surface. A radian of the curved surface is 4R-1000R.

In an embodiment of the disclosure, a radian of the curved surface is 4R-250R.

In an embodiment of the disclosure, the laser engraved structure forms a pattern on the physical vapor deposition layer. The pattern is selected from the group consisting of a graph, a number, a symbol, and a character.

In an embodiment of the disclosure, the pattern has an area, and the area is 1400-11000 mm².

In an embodiment of the disclosure, the laser engraved structure has a line width and a depth relative to the physical vapor deposition layer. The line width is 0.1-0.2 mm. The depth is 0.0005-0.005 mm.

In an embodiment of the disclosure, the laser engraved structure penetrates the physical vapor deposition layer.

The disclosure further provides a manufacturing method of a golf club head. The manufacturing method includes: providing a main body, wherein the main body has a curved surface; disposing a physical vapor deposition layer on the curved surface; and forming a laser engraved structure on the physical vapor deposition layer.

In an embodiment of the disclosure, the laser engraved structure is a recessed structure. The manufacturing method further includes: filling a dye layer in the laser engraved structure.

In an embodiment of the disclosure, the step of forming the laser engraved structure on the physical vapor deposition layer includes: making the laser engraved structure penetrate the physical vapor deposition layer.

Another aspect of the disclosure is to provide a golf club head, in which a laser engraved structure is formed on a curved surface of a main body by using the laser engraving technology, so the curved surface of the main body can appear as a stereoscopic texture. In addition, a physical vapor deposition layer is further formed on the curved surface having the laser engraved structure, so the curved surface of the main body can appear natural metallic luster and texture. Particularly, the physical vapor deposition layer formed on the curved surface has a single color, so people can feel that the curved surface is more visually stereoscopic.

The disclosure further provides a golf club head. The golf club head includes a main body and a physical vapor deposition layer. The main body has a curved surface. The curved surface has a laser engraved structure. The physical vapor deposition layer is formed on the curved surface and covers the laser engraved structure.

In an embodiment of the disclosure, the curved surface is a concave surface, a convex surface, or a raised and recessed surface. A radian of the curved surface is 4R-1000R.

In an embodiment of the disclosure, a radian of the curved surface is 4R-250R.

In an embodiment of the disclosure, the laser engraved structure forms a pattern on the physical vapor deposition layer. The pattern is selected from the group consisting of a graph, a number, a symbol, and a character.

In an embodiment of the disclosure, the pattern has an area, and the area is 1400-11000 mm².

In an embodiment of the disclosure, the laser engraved structure has a line width and a depth relative to the physical vapor deposition layer. The line width is 0.1-0.2 mm. The depth is 0.0005-0.005 mm.

The disclosure further provides a manufacturing method of a golf club head. The manufacturing method includes: providing a main body, wherein the main body has a curved surface; forming a laser engraved structure on the curved surface; and forming a physical vapor deposition layer on the curved surface, wherein the physical vapor deposition layer covers the laser engraved structure.

Accordingly, the golf club head and the manufacturing method of the disclosure form the physical vapor deposition layer on the curved surface of the main body, so the curved surface of the main body can appear a stereoscopic texture. Furthermore, the laser engraved structure can be formed on the physical vapor deposition layer by using the laser engraving technology, so the curved surface of the main body can further appear a stereoscopic texture.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a perspective view of a golf club head according to an embodiment of the disclosure;

FIG. 1B is another perspective view of FIG. 1A;

FIG. 2A to FIG. 2C are cross-sectional views of manufacturing a golf club head according to an embodiment of the disclosure;

FIG. 3 is a flow diagram of a manufacturing method of a golf club head according to an embodiment of the disclosure;

FIG. 4 is a cross-sectional view of manufacturing a golf club head according to another embodiment of the disclosure;

FIG. 5A is a perspective view of a golf club head according to another embodiment of the disclosure;

FIG. 5B is another perspective view of FIG. 5A;

FIG. 6A to FIG. 6B are cross-sectional views of manufacturing the golf club head according to another embodiment of the disclosure;

FIG. 7 is a flow diagram of a manufacturing method of a golf club head according to another embodiment of the disclosure; and

FIG. 8 is a schematic diagram of a wedge according to an embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

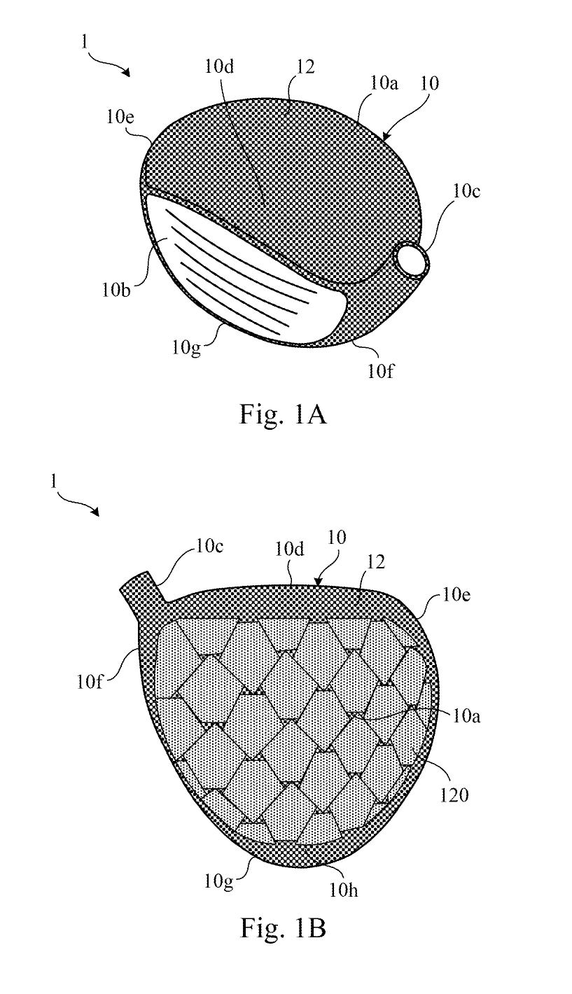

FIG. 1A is a perspective view of a golf club head 1 according to an embodiment of the disclosure. FIG. 1B is another perspective view of FIG. 1A.

As shown in FIG. 1A and FIG. 1B, in the embodiment, the golf club head 1 includes a main body 10 and a physical vapor deposition layer 12. The main body 10 of the golf club head 1 mainly includes a ground 10a, a hitting surface 10b, a hosel 10c, a crown 10d, a toe 10e, a heel 10f, a sole 10g, and a back 10h, in which the hosel 10c can be connected to a rod body (not shown) for a user to hold and perform hitting movements. The materials of the main body 10 can be carbon steel, mild steel, stainless steel (e.g., 17-4PH stainless steel), alloy steel, low alloy steel, Fe—Mn—Al alloys, nickel-based alloys, cast iron, structural steel, super alloy steel, or other metal materials such as titanium alloys, but the disclosure is not limited in this regard.

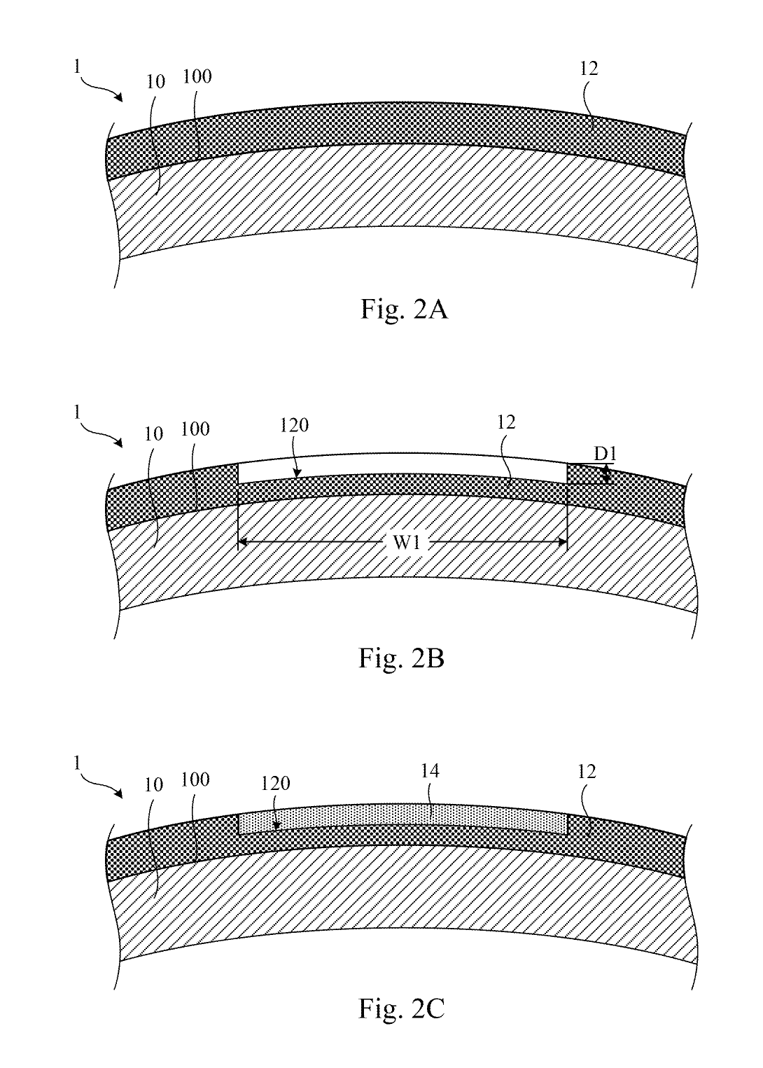

FIG. 2A to FIG. 2C are cross-sectional views of manufacturing a golf club head 1 according to an embodiment of the disclosure.

As shown in FIG. 2A to FIG. 2C, in the embodiment, the main body 10 of the golf club head 1 has a curved surface 100. A radian of the curved surface 100 is 4R-1000R. The physical vapor deposition layer 12 of the golf club head 1 is formed on the curved surface 100. The physical vapor deposition layer 12 has a laser engraved structure 120. In more detail, the laser engraved structure 120 is located at the location corresponding to the ground 10a, but the disclosure is not limited in this regard. In another embodiment, the laser engraved structure 120 can be located at the location corresponding to at least one of the hosel 10c, the crown 10d, the toe 10e, the heel 10f, the sole 10g, and the back 10h.

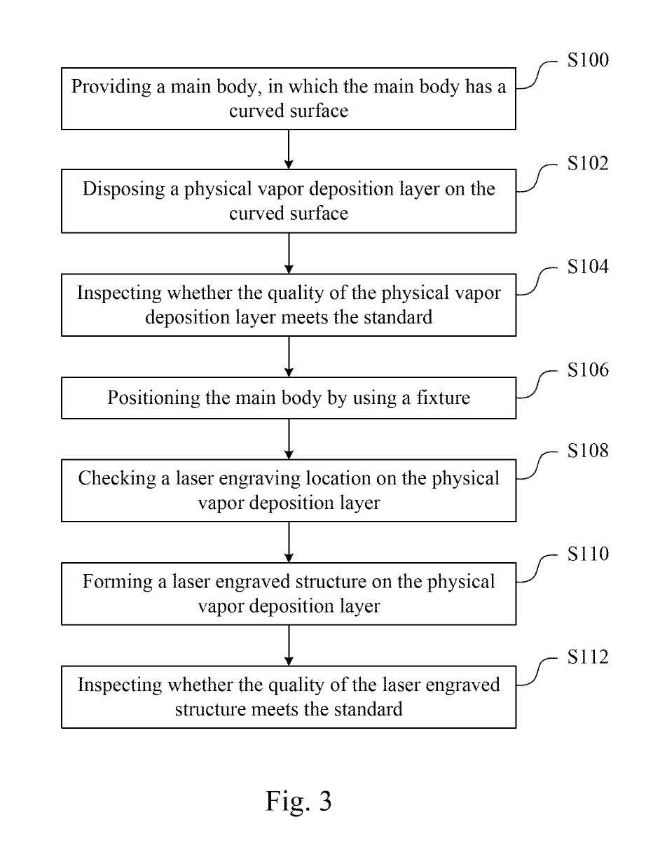

FIG. 3 is a flow diagram of a manufacturing method of a golf club head according to an embodiment of the disclosure.

As shown in FIG. 3, to manufacture the golf club head 1, the manufacturing method includes: (S100) providing a main body 10, in which the main body 10 has a curved surface 100; (S102) disposing a physical vapor deposition layer 12 on the curved surface 100, as shown in FIG. 2A; (S104) inspecting whether the quality of the physical vapor deposition layer 12 meets the standard; (S106) positioning the main body 10 by using a fixture; (S108) checking a laser engraving location on the physical vapor deposition layer 12; (S110) forming a laser engraved structure 120 on the physical vapor deposition layer 12, as shown in FIG. 2B; and (S112) inspecting whether the quality of the laser engraved structure 120 meets the standard. Therefore, the curved surface 100 of the main body 10 can appear to have a natural metallic luster and texture and a stereoscopic texture.

In practical applications, the physical vapor deposition layer 12 of the golf club head 1 can be formed on the curved surface 100 of the main body 10 by vacuum evaporating, sputtering, Ion plating, etc.

In practical applications, the materials of the physical vapor deposition layer 12 of the golf club head 1 includes metals such as titanium (Ti), titanium alloys (e.g., TiAl), gold (Au), stainless steel, chromium (Cr), zirconium (Zr), copper (Cu), nickel (Ni), or aluminum (Al), but the disclosure is not limited in this regard.

In an embodiment, the radian of the curved surface 100 can further be 4R-250R. At this range, the pattern formed by the laser engraved structure 120 on the physical vapor deposition layer 12 is clearer. However, the disclosure is not limited in this regard.

In the embodiment, the curved surface 100 of the main body 10 is a convex surface, but the disclosure is not limited in this regard. In another embodiment, the curved surface 100 of the main body 10 is a concave surface. That is, the laser engraving technology can be used to machine a concave surface or a convex surface, and the focus of the laser beam may be adjusted at any time during manufacturing.

In the embodiment, the pattern formed by the laser engraved structure 120 on the physical vapor deposition layer 12 includes graphs with special shapes and arrangement, as shown in FIG. 1B, but the disclosure is not limited in this regard. In practical applications, the pattern formed by the laser engraved structure 120 on the physical vapor deposition layer 12 can also include numbers, symbols, or characters. For example, the pattern formed by the laser engraved structure 120 on the physical vapor deposition layer 12 can be a trademark or a rod number, so as to provide marked effects and improve the aesthetic level of the main body 10.

In an embodiment, an area of the pattern formed by the laser engraved structure 120 on the physical vapor deposition layer 12 is 1400-11000 mm². In practical applications, the pattern with foregoing range of area can also be used to the back of a wedge or the crown of a wood club. However, the disclosure is not limited in this regard.

As shown in FIG. 2B, in the embodiment, the laser engraved structure 120 has a line width W1 and a depth D1 relative to the physical vapor deposition layer 12. The line width W1 is 0.1-0.2 mm, and the depth D1 is 0.0005-0.005 mm, but the disclosure is not limited in this regard.

Furthermore, the laser engraved structure 120 on the physical vapor deposition layer 12 is a recessed structure. The golf club head 1 further includes a dye layer 14. The dye layer 14 is filled in the laser engraved structure 120. To manufacture the golf club head 1, the manufacturing method can further include: (S114) filling the dye layer 140 in the laser engraved structure 120. To perform the step (S114), the dye layer 14 can be formed on the physical vapor deposition layer 12 by spin coating to fill the dye layer 14 in the laser engraved structure 120, and the dye layer 14 on the surface of the physical vapor deposition layer 12 is then removed to make the residual dye layer 14 remain in the laser engraved structure 120. Therefore, the laser engraved structure 120 on the curved surface 100 can appear a color different from that of the physical vapor deposition layer 12, as shown in FIG. 1B an FIG. 2C.

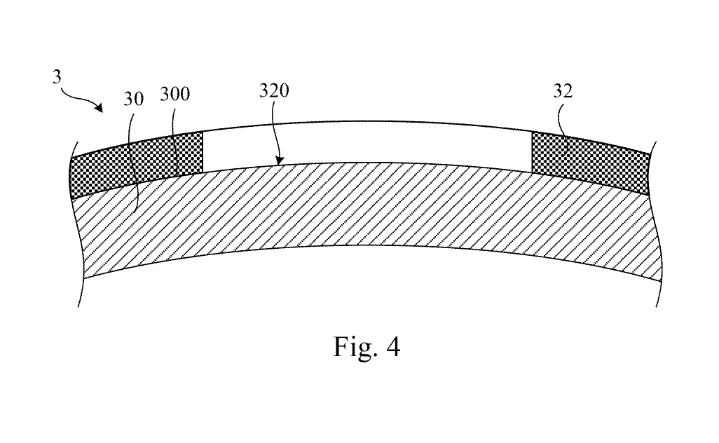

FIG. 4 is a cross-sectional view of manufacturing a golf club head 3 according to another embodiment of the disclosure.

As shown in FIG. 4, in the embodiment, the golf club head 3 includes a main body 30 and a physical vapor deposition layer 32. The main body 30 of the golf club head 3 has a curved surface 300. A radian of the curved surface is 5R-1000R. The physical vapor deposition layer 32 of the golf club head 3 is formed on the curved surface 300. The physical vapor deposition layer 32 has a laser engraved structure 320. To manufacture the golf club head 3, the manufacturing method can be referred to foregoing steps (S100) to (s112), and it is not repeated again here. It should be pointed out that a difference between the present embodiment and the embodiment in FIG. 2A to FIG. 2C is that the laser engraved structure 320 in the present embodiment penetrates the physical vapor deposition layer 32. In other words, the step (S110) in the present embodiment is further to make the laser engraved structure 320 penetrate the physical vapor deposition layer 32. That is, the physical vapor deposition layer 32 is laser-engraved to expose the curved surface 300 of the main body 30. Therefore, the golf club head 3 can appear the color of the physical vapor deposition layer 32 and the color of the main body 30 at the same time.

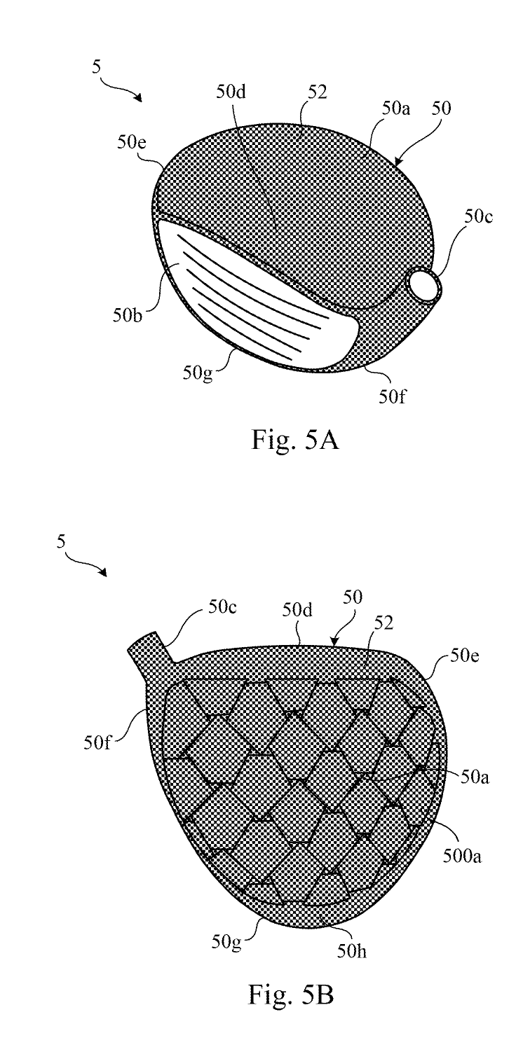

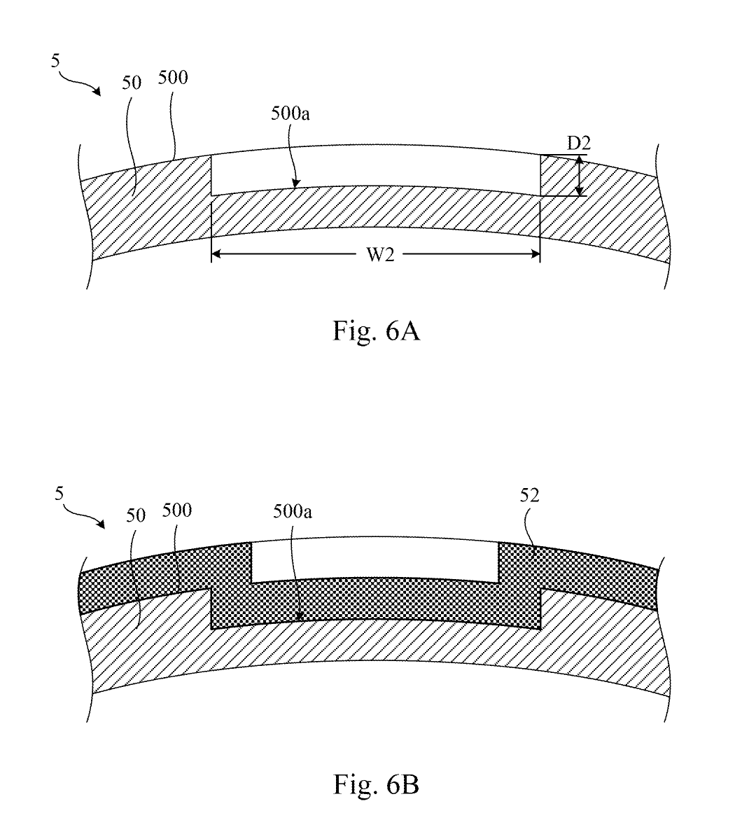

FIG. 5A is a perspective view of a golf club head 5 according to another embodiment of the disclosure. FIG. 5B is another perspective view of FIG. 5A. FIG. 6A to FIG. 6B are cross-sectional views of manufacturing the golf club head 5 according to another embodiment of the disclosure.

As shown in FIG. 5A to FIG. 6B, in the embodiment, the golf club head 5 includes a main body 50 and a physical vapor deposition layer 52. The main body 50 of the golf club head 5 mainly includes a ground 50a, a hitting surface 50b, a hosel 50c, a crown 50d, a toe 50e, a heel 50f, a sole 50g, and a back 50h. The main body 50 has a curved surface 500. The curved surface 500 has a laser engraved structure 500a. A radian of the curved surface 500 is 4R-1000R. The physical vapor deposition layer 52 is formed on the curved surface 500 and covers the laser engraved structure 500a. In more detail, the laser engraved structure 500a is located at a location corresponding to the ground 50a, but the disclosure is not limited in this regard. In another embodiment, the laser engraved structure 500a can be located at the location corresponding to at least one of the hosel 50c, the crown 50d, the toe 50e, the heel 50f, the sole 50g, and the back 50h.

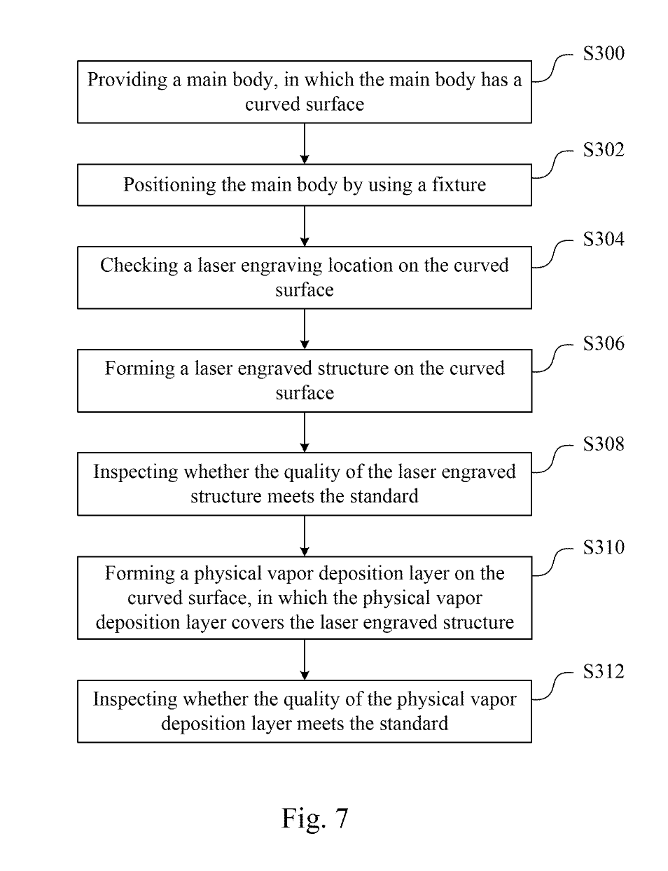

FIG. 7 is a flow diagram of a manufacturing method of a golf club head according to another embodiment of the disclosure.

As shown in FIG. 7, in the embodiment, to manufacture the golf club head 5, the manufacturing method includes: (S300) providing a main body 50, in which the main body 50 has a curved surface 500; (S302) positioning the main body 50 by using a fixture; (S304) checking a laser engraving location on the curved surface 500; (S306) forming a laser engraved structure 500a on the curved surface 500, as shown in FIG. 6A; (S308) inspecting whether the quality of the laser engraved structure 500a meets the standard; (S310) forming a physical vapor deposition layer 52 on the curved surface 500, in which the physical vapor deposition layer 52 covers the laser engraved structure 500a, as shown in FIG. 5B and FIG. 6B; and (S312) inspecting whether the quality of the physical vapor deposition layer 52 meets the standard. Therefore, the curved surface 500 of the main body 50 can appear to have a natural metallic luster and texture and provide a stereoscopic texture. Moreover, because the physical vapor deposition layer 52 formed on the curved surface 500 has a single color, the physical vapor deposition layer 52 with an uneven shape (owing to the laser engraved structure 500a on the physical vapor deposition layer 52) can make people feel that the curved surface is more visually stereoscopic

In practical applications, the physical vapor deposition layer 52 of the golf club head 5 can be formed on the curved surface 500 of the main body 50 by vacuum evaporating, sputtering, Ion plating, and etc.

In practical applications, the materials of the physical vapor deposition layer 52 of the golf club head 5 includes metals such as titanium, titanium alloys, gold, stainless steel, chromium, zirconium, copper, nickel, or aluminum, but the disclosure is not limited in this regard.

In an embodiment, the radian of the curved surface 500 can further be 4R-250R. At this range, the pattern formed by the laser engraved structure 500a on the curved surface 500 of the main body 50 is clearer. However, the disclosure is not limited in this regard.

In the embodiment, the curved surface 500 of the main body 50 is a convex surface, but the disclosure is not limited in this regard. In another embodiment, the curved surface 500 of the main body 50 is a concave surface. In another embodiment, the curved surface 500 of the main body 50 is a raised and recessed surface. That is, the laser engraving technology can be used to machine a concave surface or a convex surface, and the focus of the laser beam must be adjusted at any time during manufacturing.

In the embodiment, the pattern formed by the laser engraved structure 500a on the curved surface 500 of the main body 50 includes graphs with special shapes and arrangement, as shown in FIG. 5B, but the disclosure is not limited in this regard. In practical applications, the pattern formed by the laser engraved structure 500a on the curved surface 500 of the main body 50 can also include numbers, symbols, or characters. For example, the pattern formed by the laser engraved structure 500a on the curved surface 500 of the main body 50 can be a trademark or a rod number, so as to provide marked effects and improve the aesthetic level of the main body 50.

In an embodiment, an area of the pattern formed by the laser engraved structure 500a on the curved surface 500 of the main body 50 is 1400-11000 mm². In practical applications, the pattern with foregoing range of area can also be used to the back of a wedge or the crown of a wood club. However, the disclosure is not limited in this regard.

As shown in FIG. 6B, in the embodiment, the laser engraved structure 500a has a line width W2 and a depth D2 relative to the main body 50. The line width W2 is 0.1-0.2 mm, and the depth D2 is 0.0005-0.005 mm, but the disclosure is not limited in this regard.

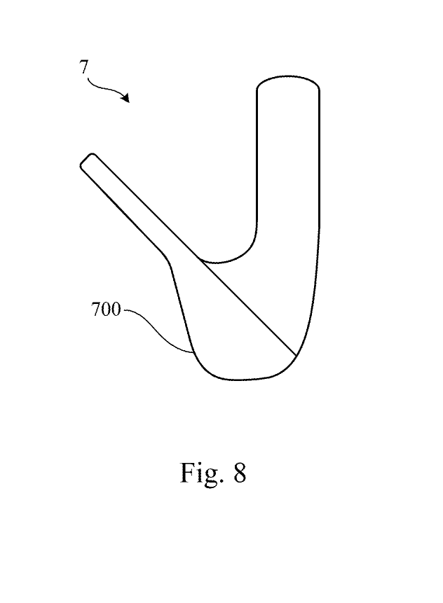

FIG. 8 is a schematic diagram of a wedge 7 according to an embodiment of the disclosure. As shown in FIG. 8, in the embodiment, the back of the wedge 7 has a curved surface 700, so the foregoing manufacturing methods of the disclosure can be applied to the curved surface 700 of the wedge 7 to appear the stereoscopic pattern shown in FIG. 8.

According to the foregoing recitations of the embodiments of the disclosure, it can be seen that a golf club head and a manufacturing method thereof are about to form a physical vapor deposition layer on a curved surface of a main body, so the curved surface of the main body can appear natural metallic luster and texture. Furthermore, a laser engraved structure is formed on the physical vapor deposition layer by using laser engraving technology, so the curved surface of the main body can further appear as a stereoscopic texture. In addition, the laser engraved structure is filled with a dye layer, so the laser engraved structure can appear a color different from that of the physical vapor deposition layer. The disclosure further provides a golf club head according to another embodiment, in which a laser engraved structure is formed on a curved surface of a main body by using the laser engraving technology, so the curved surface of the main body can appear as a stereoscopic texture. In addition, a physical vapor deposition layer is further formed on the curved surface having the laser engraved structure, so the curved surface of the main body can appear natural metallic luster and texture. Particularly, the physical vapor deposition layer formed on the curved surface has a single color, so people can feel that the curved surface is more visually stereoscopic.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A golf club head, comprising:
a main body having a curved surface; and
a physical vapor deposition layer formed on the curved surface, the physical vapor deposition layer having a laser engraved structure.

2. The golf club head of claim 1, wherein the laser engraved structure is a recessed structure, the golf club head further comprises a dye layer, and the dye layer is filled in the laser engraved structure.

3. The golf club head of claim 1, wherein the curved surface is a concave surface, a convex surface, or a raised and recessed surface, and a radian of the curved surface is 4R-1000R.

4. The golf club head of claim 1, wherein a radian of the curved surface is 4R-250R.

5. The golf club head of claim 1, wherein the laser engraved structure forms a pattern on the physical vapor deposition layer, and the pattern is selected from the group consisting of a graph, a number, a symbol, and a character.

6. The golf club head of claim 5, wherein the pattern has an area, and the area is 1400-11000 mm².

7. The golf club head of claim 1, wherein the laser engraved structure has a line width and a depth relative to the physical vapor deposition layer, the line width is 0.1-0.2 mm, and the depth is 0.0005-0.005 mm.

8. The golf club head of claim 1, wherein the laser engraved structure penetrates the physical vapor deposition layer.

9. A manufacturing method of a golf club head, comprising:
providing a main body, wherein the main body has a curved surface;
disposing a physical vapor deposition layer on the curved surface; and
forming a laser engraved structure on the physical vapor deposition layer.

10. The manufacturing method of claim 9, wherein the laser engraved structure is a recessed structure, and the manufacturing method further comprises:
filling a dye layer in the laser engraved structure.

11. The manufacturing method of claim 9, wherein the step of forming the laser engraved structure on the physical vapor deposition layer comprises:
making the laser engraved structure penetrate the physical vapor deposition layer.

12. A golf club head, comprising:
a main body having a curved surface, wherein the curved surface has a laser engraved structure; and
a physical vapor deposition layer formed on the curved surface and covering the laser engraved structure.

13. The golf club head of claim 12, wherein the curved surface is a concave surface, a convex surface, or a raised and recessed surface, and a radian of the curved surface is 4R-1000R.

14. The golf club head of claim 12, wherein a radian of the curved surface is 4R-250R.

15. The golf club head of claim 12, wherein the laser engraved structure forms a pattern on the physical vapor deposition layer, and the pattern is selected from the group consisting of a graph, a number, a symbol, and a character.

16. The golf club head of claim 15, wherein the pattern has an area, and the area is 1400-11000 mm².

17. The golf club head of claim 12, wherein the laser engraved structure has a line width and a depth relative to the physical vapor deposition layer, the line width is 0.1-0.2 mm, and the depth is 0.0005-0.005 mm.

18. A manufacturing method of a golf club head, comprising:
providing a main body, wherein the main body has a curved surface;
forming a laser engraved structure on the curved surface; and
forming a physical vapor deposition layer on the curved surface, wherein the physical vapor deposition layer covers the laser engraved structure.
